(19) United States
(12) Patent Application Publication
(10) Pub. No.: US 2014/0350874 A1
(43) Pub. Date: Nov. 27, 2014

(54) SENSING SYSTEM AND METHOD FOR DETECTING AND GRAPHICALLY DISPLAYING ELECTRICITY USAGE INFORMATION

(71) Applicant: D-Link Corporation, Taipei City (TW)

(72) Inventors: Chih-Yu LIN, Taipei City (TW); Jia-Liang LIAO, Taipei City (TW); Jia-Ming LIANG, Taipei City (TW); Yu-Chee TSENG, Taipei City (TW); Cheng-Yi YAN, Taipei City (TW)

(73) Assignee: D-Link Corporation, Taipei City (TW)

(21) Appl. No.: 13/950,345

(22) Filed: Jul. 25, 2013

(30) Foreign Application Priority Data
May 21, 2013 (TW) 102117846

(51) Int. Cl. G01R 13/02; G01R 21/00

(52) U.S. Cl. CPC G01R 13/02; G01R 21/00
USPC 702/62

(57) ABSTRACT

The present invention is to provide a sensing method applicable to a sensing system including at least one detecting device and a mobile communication device, wherein the detecting device is electrically connected between an electrical appliance and a power supply unit for detecting usage information (e.g., voltage value, current value, power value, etc.) of the electricity transmitted from the power supply unit to the electrical appliance, and the mobile communication device is wirelessly connected to the detecting device and is able to transmit setting data inputted by a user to the detecting device so that, after receiving the setting data, the detecting device is able to periodically transmit the electricity usage information to the mobile communication device, allowing the mobile communication device to convert the electricity usage information into a detecting chart and graphically display the detecting chart on a screen of the mobile communication device.

### FIELD OF THE INVENTION

The present invention relates to a sensing method, more particularly to a sensing method applicable to a sensing system including at least one detecting device and a mobile communication device, wherein the detecting device is electrically connected between an electrical appliance and a power supply unit for detecting usage information (e.g., voltage value, current value, power value, etc.) of the electricity transmitted from the power supply unit to the electrical appliance, and the mobile communication device is wirelessly connected to the detecting device and is able to transmit setting data inputted by a user to the detecting device so that, after receiving the setting data, the detecting device is able to periodically transmit the electricity usage information to the mobile communication device, allowing the mobile communication device to convert the electricity usage information into a detecting chart and graphically display the detecting chart on a screen of the mobile communication device.

### BACKGROUND OF THE INVENTION

Due to the aggravation of such environmental problems as global warming, climate change, and the greenhouse effect, it is now imperative to save energy and reduce carbon dioxide emissions. The ongoing global recession has also made it common practice for consumers to pay attention to the power consumption data of an electrical appliance to be bought—be it an electric lamp, an air conditioner, an electric fan, or a refrigerator—and use the data as a major reference when making the decision of purchase. Aside from choosing power-saving electrical appliances, the key to minimizing the use of electricity lies, in fact, in the habit of use.

For example, one who has finished using an electrical appliance may leave the electrical appliance turned on so that it can be conveniently used at a later time. However, as an electrical appliance which is powered on but not in use is still in operation and consumes electricity, leaving it powered on may bring a premature end to its service life. If an electrical appliance is always turned off but not unplugged when not in use, power consumption may still take place, and the electricity consumed can be considerable in the long run. An air conditioner, for instance, typically has a 10 W standby power when plugged in but not in operation, and a washing machine has an average standby power of about 2 W. According to a survey conducted by the International Energy Agency, the power consumed by an electrical appliance in the standby mode accounts for about 3% to 11% of its total power consumption. Therefore, all electrical appliances, except for those which must be powered on 24 hours a day (e.g., refrigerators and security devices), should be completely cut off from power when not in use, with a view to preventing wasteful use of energy. Nevertheless, unplugging all existing electrical appliances not only compromises the convenience of subsequent use, but also may lead to a mess of power cords. More importantly, the energy-saving effect of unplugging an electrical appliance cannot be known immediately. As a result, the aforesaid energy-saving measures are rarely thoroughly practiced.

The present inventor has found during research in the related field that a major factor influencing one's habit of use of electricity is, as stated above, “not knowing the energy-saving effect actually achieved”. As not everyone is familiar with the charging schemes of a power company or can readily figure out the substantial benefit of an energy-saving action taken, the significant effects of an energy-saving action are not clearly known. Moreover, once an electrical appliance has been used for years, its internal components may have aged or been damaged such that power consumption increases dramatically, which could in turn result in disasters.

In consideration of the above, the present inventor came up with the idea of designing a sensing system for detecting the electricity usage data of an electrical appliance and converting the data into a comprehensible chart. Not only that, the sensing system will take advantage of the portability and high processing efficiency of the increasingly popular mobile communication devices nowadays, allowing the user to know, in real time and without limitation of space, the power currently consumed by an electrical appliance, thus prompting the user to take necessary energy-saving actions. The issue to be addressed by the present invention, therefore, is to design the structure and process flow of such a sensing system.

### BRIEF SUMMARY OF THE INVENTION

In view of the fact that one can hardly know, let alone manage, the power consumption of an electrical appliance, the inventor of the present invention incorporated years of practical experience into extensive experiment and tests and finally succeeded in developing a sensing system and method for detecting and graphically displaying electricity usage information. The sensing system and method are intended to effectively notify the user of the electricity consumed by an electrical appliance and thereby contribute to environmental protection.

It is an object of the present invention to provide a sensing method for detecting and graphically displaying electricity usage information, wherein the sensing method is applicable to at least one detecting device and a mobile communication device. The detecting device is mounted to an electrical appliance and is electrically connected to a power supply unit; thus, the electrical appliance can receive an electric signal transmitted from the power supply unit through the detecting device. The detecting device includes a detecting module, a storage module, and a transmission module. The detecting module is configured for detecting the electric signal transmitted from the power supply unit and generating electricity usage information according to the electric signal detected, wherein the electricity usage information at least includes a detected time (e.g., the startup time or the duration of use of the electrical appliance) and detected data (e.g., a voltage value, a current value, a power value, etc.). The storage module is configured for storing the electricity usage information generated by the detecting module. The mobile communication device is configured for connecting with the transmission module of the detecting device and with a cloud server through wireless transmission (e.g., Bluetooth or Wi-Fi). The sensing method is carried out as follows. To begin with, the mobile communication device scans for and connects with the transmission module of the detecting device within the wireless transmission range of the mobile communication device. Through the detecting device, the mobile communication device obtains the type and the usage state of the electrical appliance. The mobile communication device then displays the type and the usage state obtained of the electrical appliance and receives setting data inputted by the user for the electrical appliance, wherein the setting data include an electricity value sampling rate (e.g., 1 Hz or 10 Hz) and an electricity upload period (e.g., every second, every minute, or every hour). Afterward, the mobile communication device transmits the setting data for the electrical appliance to the detecting device so that, after receiving the setting data, the detecting device can periodically detect the electricity usage information of the electrical appliance according to the electricity sampling rate and transmit the electricity usage information to the mobile communication device according to the electricity upload period, allowing the mobile communication device to upload the electricity usage information to the cloud server and store the electricity usage information thereinto. Moreover, after receiving the electricity usage information of the electrical appliance, the mobile communication device converts the detected data into a detecting chart according to the detected time in the electricity usage information and displays the detecting chart. According to the above, the user of the sensing method of the present invention can easily set each of the at least one detecting device via the mobile communication device and obtain the detecting chart corresponding to each electrical appliance in order to determine which of the at least one electrical appliance consumes the most electricity or shows signs of aging. The user can therefore change his or her habit of use of electricity in a timely manner.

It is another object of the present invention to provide the foregoing sensing method, wherein the detecting device further stores a set of user data (e.g., a username and a password). Once finding the detecting device by scanning, the mobile communication device is required to transmit verification data to the detecting device, and the mobile communication device won't be able to connect with the detecting device unless the detecting device determines that the verification data match the user data. Thus, data related to the at least one electrical appliance are kept from theft, and security of the sensing system is ensured.

### BRIEF DESCRIPTION OF THE SEVERAL VIEWS OF THE DRAWINGS

The technical features, process flow, and objects of the present invention will be best understood by referring to the following detailed description of some illustrative embodiments in conjunction with the accompanying drawings, in which:

FIG. 1 schematically shows the first preferred embodiment of the sensing system of the present invention;

FIG. 2 is the flowchart of the sensing method employed by the sensing system of the present invention;

FIG. 3 schematically shows the setting interface generated by the sensing method of the present invention;

FIG. 4 schematically shows the detecting interface of the sensing method of the present invention; and

FIG. 5 schematically shows the second preferred embodiment of the sensing system of the present invention.

### DETAILED DESCRIPTION OF THE INVENTION

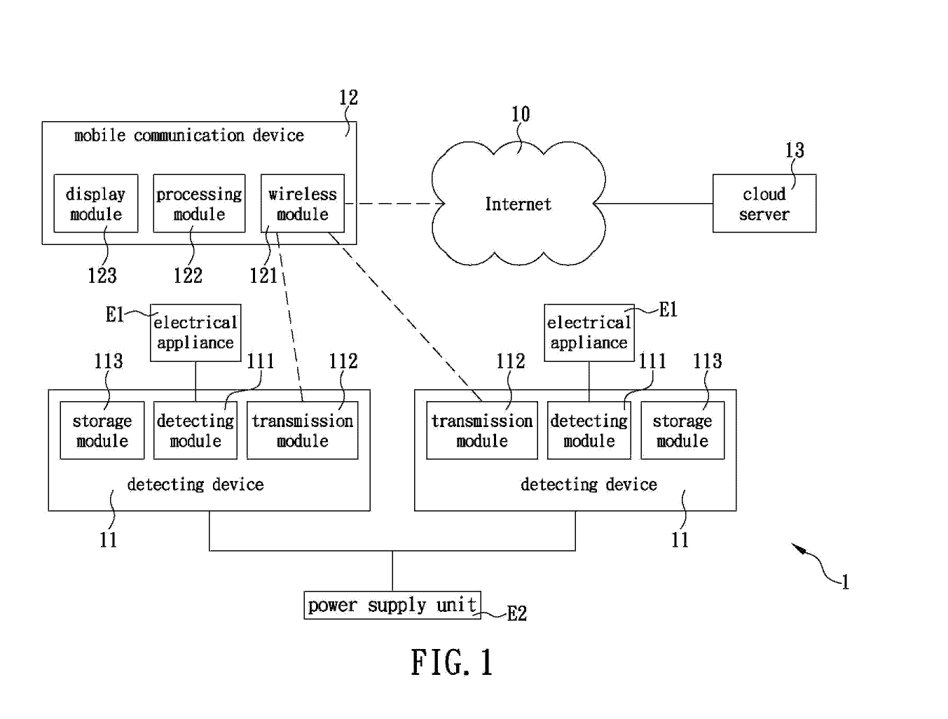

The present invention discloses a sensing system for detecting and graphically displaying electricity usage information and a method thereof. Referring to FIG. 1 for the first preferred embodiment of the present invention, the sensing system 1 includes at least one detecting device 11 and a mobile communication device 12. Each detecting device 11, which may be an adapter, a power strip, or a like connecting device, is mounted to an electrical appliance E1 and electrically connected to a power supply unit E2. Thus, each electrical appliance E1 can receive an electric signal transmitted from the power supply unit E2 through the corresponding detecting device 11 and be driven to operate by the electric signal.

Each detecting device 11 includes a detecting module 111, a transmission module 112, and a storage module 113. The detecting module 111 is configured for detecting the electric signal transmitted from the power supply unit E2 and generating electricity usage information according to the electric signal detected, wherein the electricity usage information corresponds to the electrical appliance E1 to which the detecting module 111 is mounted and at least includes a detected time (e.g., the startup time of the electrical appliance E1, i.e., the time at which the electrical appliance E1 is turned on, or the duration of use of the electrical appliance E1) and detected data (e.g., a voltage value, a current value, a power value, etc.). The electricity usage information generated by the detecting module 111 is stored into the storage module 113. The mobile communication device 12 includes a wireless module 121, a processing module 122, and a display module 123. The wireless module 121 is configured for connecting with the transmission module 112 of each detecting device 11 through wireless transmission. In this embodiment, the wireless module 121 makes the aforesaid connection by the Bluetooth transmission technology and can further connect to the Internet 10 by the Wi-Fi technology in order to transmit data to and from a cloud server 13.

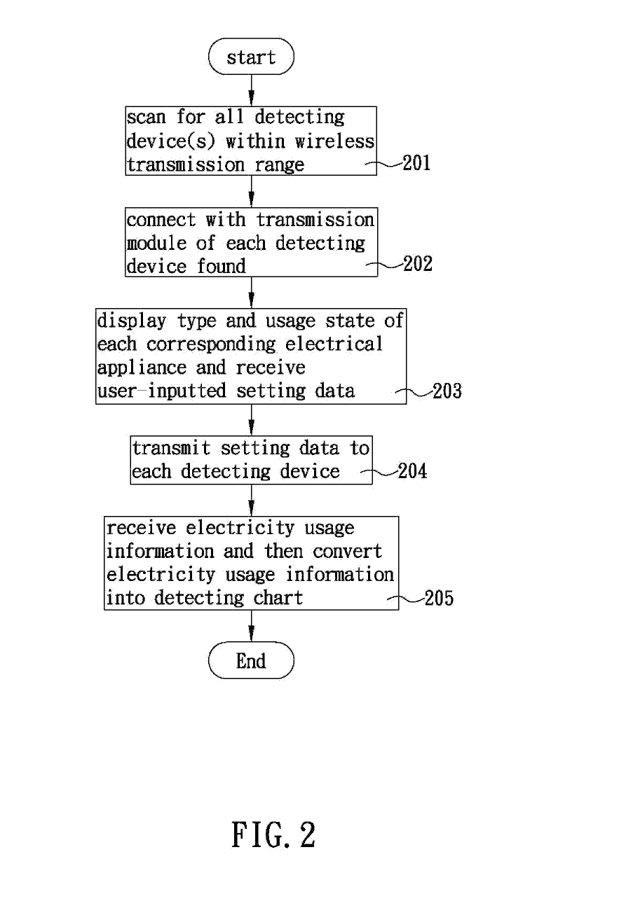

Referring to FIG. 2 in conjunction with FIG. 1, the sensing method of the present invention includes the following steps to be performed by the processing module 122 of the mobile communication device 12 when the user turns on the mobile communication device 12 to detect the electricity usage of each electrical appliance E1:

(201) Through the wireless module 121, the processing module 122 scans for all the detecting device(s) 11 within the wireless transmission range of the wireless module 121. In this embodiment, the wireless transmission range is the Bluetooth transmission range of the mobile communication device 12. In other embodiments, however, the wireless module 121 may scan for the detecting device(s) 11 through Wi-Fi, in which case “the wireless transmission range” can be defined by a local area network in the user's house.

(202) After finding a certain detecting device 11 by scanning, the processing module 122 connects with the transmission module 112 of the detecting device 11 and obtains the type and the usage state of the corresponding electrical appliance E1. The type of the electrical appliance E1 is intended to facilitate identification and may be, for example, an electric lamp or a refrigerator. The type of the electrical appliance E1 may be represented by be code. “The usage state” refers to the current operating state of the electrical appliance E1 and may include the total time for which the electrical appliance E1 has been in operation since it was last turned on.

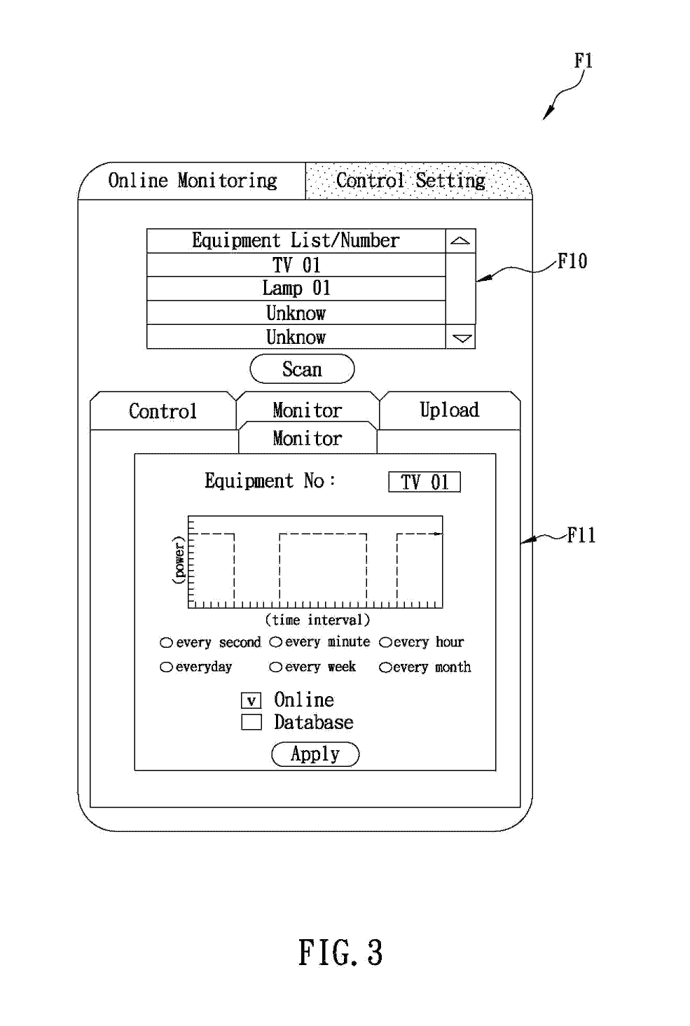

(203) The processing module 122 displays the type and the usage state of the electrical appliance E1 via the display module 123 and receives setting data inputted by the user. The setting data include an electricity value sampling rate (i.e., the capture frequency of the detecting device 11, such as 1 Hz, 10 Hz, or 100 Hz) and an electricity upload period (e.g., every second, every minute, every hour, or everyday). Referring to FIG. 3, the processing module 122 generates a setting interface F1 on the display module 123, wherein the setting interface F1 includes an equipment list F10 and a setting menu F11. The equipment list F10 in FIG. 3 corresponds to a case in which the mobile communication device 12 is connected with two detecting devices 11, and the types of the two corresponding electrical appliances E1 are shown as “TV 01” and “Lamp 01”. The user can select and set the setting data through the setting interface F1. In particular, the electricity value sampling rate and the electricity upload period can be selected from the setting menu F11.

(204) Referring to FIGS. 1˜4, the processing module 122 also generates a detecting interface F2 on the display module 123 so that the user can activate the detecting and analyzing functions of the sensing system 1 via the detecting interface F2. Once the detecting and analyzing functions of the sensing system 1 are activated, the processing module 122 transmits the setting data to the transmission module 112 of the detecting device 11 through the wireless module 121, in order for the detecting device 11 to capture the electric signal according to the electricity value sampling rate in the setting data, to generate the electricity usage information, and to send the electricity usage information to the wireless module 121 of the mobile communication device 12 via the transmission module 112 of the detecting device 11 according to the electricity upload period. The mobile communication device 12 will in turn upload the electricity usage information to the cloud server 13.

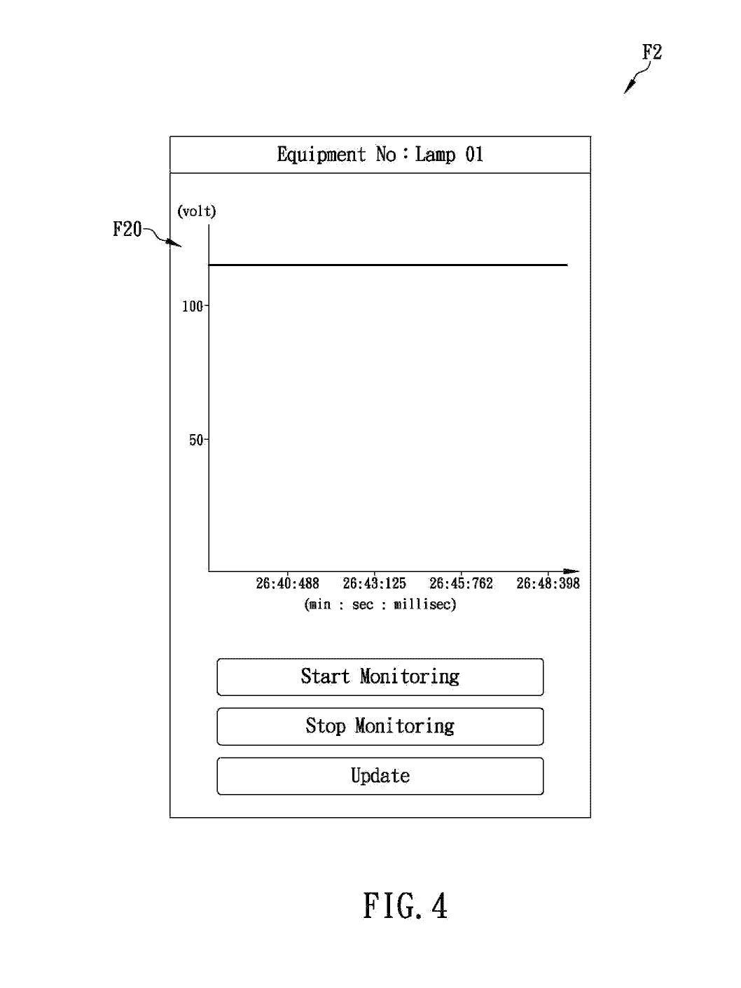

(205) Upon receiving the electricity usage information sent from the detecting device 11, the processing module 122 generates a detecting chart F20 by converting the detected time and detected data in the electricity usage information and displays the detecting chart F20 on the display module 123. The horizontal axis of the chart represents the time at which the detecting device 11 captures the electric signal, and the vertical axis of the chart indicates values of the detected data (e.g., the detected voltages as shown in FIG. 4, or values of current, power, etc.). It should be noted that the detecting chart F20 in FIG. 4 corresponds to a single detecting device 11 only. If the mobile communication device 12 is simultaneously connected with a plurality of detecting devices 11, the mobile communication device 12 can integrate multiple sets of detected data into a single detecting chart F20 (e.g., by showing the detected data of plural electrical appliances E1 in different colors respectively).

Thus, the sensing method of the present invention not only allows the user to conveniently set various detecting devices 11 by means of the mobile communication device 12, but also enables the mobile communication device 12 (if installed with a specific application program or App) to convert the electricity usage information of each electrical appliance E1 into a corresponding detecting chart F20, from which the user can easily determine if any electrical appliance E1 has consumed too much electricity or which electrical appliance(s) E1 has/have shown abnormal electricity usage information as a possible sign of aging. The user can therefore adjust his or her habit of use of electricity based on the detecting chart F20 in order to save energy effectively.

Referring again to FIG. 1, the storage module 113 of each detecting device 11 further stores a set of user data (e.g., a username and a password set by the user). Once a certain detecting device 11 is found by the mobile communication device 12 to be within its wireless transmission range, the mobile communication device 12 is required to send verification data to the detecting device 11, and only when the detecting device 11 determines that the verification data match the user data will the mobile communication device 12 be allowed to connect with the detecting device 11. This technical feature enhances the security and confidentiality of the sensing system.

In the foregoing embodiment, the cloud server 13, after the mobile communication device 12 has uploaded thereto the electricity usage information, arranges the electricity usage information and stores it as an electricity usage record. Hence, when converting the electricity usage information, the mobile communication device 12 can also make reference to the electricity usage record in order to notify the user whether there is an increasing trend of electricity consumption (e.g., by comparing the current electricity usage information with the electricity usage record of a month or a year ago).

It should be pointed out that, in this embodiment, the detecting device 11 with which the mobile communication device 12 is connected transmits the electricity usage information to the mobile communication device 12 before the mobile communication device 12 uploads the electricity usage information to the cloud server 13. In other preferred embodiments of the present invention, however, the transmission module 112 may, after the detecting device 11 receives the setting data, directly upload the electricity usage information to the cloud server 13 through Wi-Fi according to the electricity upload period, without the assistance of the mobile communication device 12.

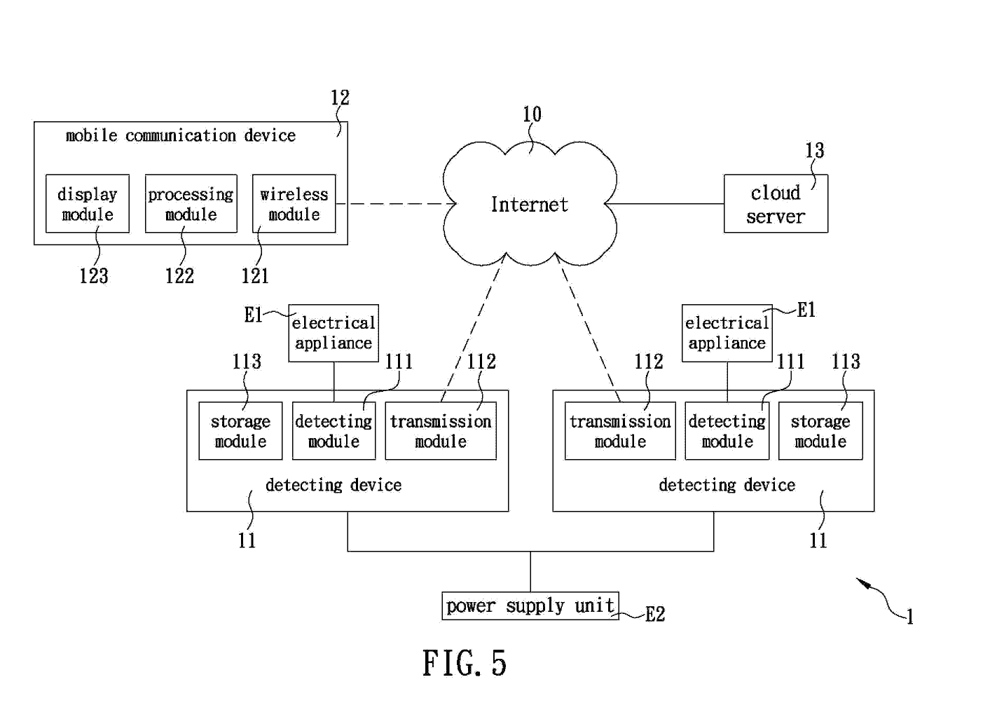

Please refer to FIG. 5 for the second preferred embodiment of the present invention. In this embodiment, the sensing system 1 is also composed of a plurality of detecting devices 11 and a mobile communication device 12, and yet the transmission module 112 of each detecting device 11 is configured for directly connecting to the Internet 10 through Wi-Fi. Therefore, the mobile communication device 12 can find the detecting devices 11 by scanning through the Internet 10. Even if the user is away from home, a remote connection can be made to the detecting devices 11 via the Internet 10 to enable setting and detection.

In addition, an application program (App) for use in the mobile communication device 12 can be designed for the sensing system 1 in each of the first and the second embodiments, for the purpose of activating or deactivating the electric signal capturing function of each detecting device 11, or further setting the period in which each detecting device 11 is to capture the electric signal. For example, the setting data further include a scheduled time, and each detecting device 11 having received the setting data will determine, through the corresponding detecting module 111 at a predetermined interval, whether the current time matches the scheduled time (e.g., from 8 am to 10 pm, Monday through Friday). A detecting device 11 having determined that the current time does not match the scheduled time will cut off the electric signal transmitted from the power supply unit E2, and only if the current time is determined to match the scheduled time will the detecting device 11 capture the electric signal according to the electricity value sampling rate and generate the electricity usage information.

While the invention herein disclosed has been described by means of specific embodiments, numerous modifications and variations could be made thereto by those skilled in the art without departing from the scope of the invention set forth in the claims.

What is claimed is:

1. A sensing method for detecting and graphically displaying electricity usage information, the sensing method being applicable to a sensing system comprising at least a detecting device and a mobile communication device, the detecting device being mounted to an electrical appliance and electrically connected to a power supply unit so that the electrical appliance can receive an electric signal transmitted from the power supply unit through the detecting device, the detecting device being configured to detect the electric signal transmitted from the power supply unit and generate electricity usage information according to the electric signal detected, the electricity usage information comprising a detected time and detected data, the mobile communication device being configured to connect with the detecting device through wireless transmission, the sensing method comprising the steps, to be performed by the mobile communication device, of:
scanning for the detecting device within a wireless transmission range and wirelessly connecting with the detecting device thus found;
obtaining a type and a usage state of the electrical appliance through the detecting device;
displaying the type and the usage state obtained of the electrical appliance and receiving setting data inputted by a user for the electrical appliance, wherein the setting data comprise an electricity value sampling rate and an electricity upload period;
transmitting the setting data to the detecting device so that, after receiving the setting data, the detecting device is able to periodically detect the electricity usage information according to the electricity value sampling rate and transmit the electricity usage information to the mobile communication device according to the electricity upload period, in order for the electricity usage information to be uploaded to and stored into a cloud server through the mobile communication device; and
converting, upon receiving the electricity usage information, the detected data into an detecting chart according to the detected time in the electricity usage information and displaying the detecting chart.

2. The sensing method of claim 1, wherein the detecting device stores a set of user data, and the mobile communication device is required, upon finding the detecting device within the wireless transmission range by scanning, to transmit verification data to the detecting device and cannot connect with the detecting device unless the detecting device determines that the verification data match the user data.

3. The sensing method of claim 2, wherein the setting data for the electrical appliance further comprise a scheduled time, and the detecting device, upon receiving the setting data for the electrical appliance and determining that a current time does not match the scheduled time in the setting data, cuts off the electric signal transmitted from the power supply unit.

4. A sensing system for detecting and graphically displaying electricity usage information, comprising:
at least a detecting device, wherein the detecting device is mounted to an electrical appliance and electrically connected to a power supply unit so that the electrical appliance can receive an electric signal transmitted from the power supply unit through the detecting device, the detecting device comprises a detecting module, a storage module, and a transmission module, the detecting module is configured to detect the electric signal transmitted from the power supply unit and generate electricity usage information according to the electric signal detected, the electricity usage information comprises a detected time and detected data, and the storage module is configured to store the electricity usage information generated by the detecting module; and
a mobile communication device comprising a wireless module, a display module, and a processing module, wherein the wireless module is configured to scan for the detecting device within a wireless transmission range of the wireless module and connect with the detecting device thus found in order to obtain a type and a usage state of the electrical appliance, the display module is configured to display the type and the usage state obtained of the electrical appliance, the processing module is respectively connected to the wireless module and the display module, the processing module is configured to receive setting data for the electrical appliance inputted by a user after the wireless module connects with the transmission module of the detecting device, the setting data for the electrical appliance comprise an electricity value sampling rate and an electricity upload period, the processing module is also configured to transmit the setting data to the transmission module of the detecting device through the wireless module, so as for the detecting device to, after receiving the setting data, periodically detect the electricity usage information of the electrical appliance according to the electricity value sampling rate and transmit the electricity usage information to the wireless module of the mobile communication device through the transmission module of the detecting device according to the electricity upload period, the electricity usage information is further uploaded to a cloud server and stored therein by the processing module of the mobile communication device through the wireless module, and the processing module is also configured to, upon receiving the electricity usage information of the electrical appliance, convert the detected data in the electricity usage information into a detecting chart according to the detected time in the electricity usage information and display the detecting chart through the display module.

5. The sensing system of claim 4, wherein the wireless module of the mobile communication device is configured to connect with the transmission module of the detecting device via Bluetooth.

6. The sensing system of claim 4, wherein the wireless module of the mobile communication device is configured to connect with the transmission module of the detecting device via Wi-Fi.

7. The sensing system of claim 4, wherein the detecting device is configured to, after receiving the setting data for the electrical appliance, upload the electricity usage information of the electrical appliance to the cloud server and store the electricity usage information into the cloud server through the transmission module of the detecting device according to the electricity upload period.

8. The sensing system of claim 4, wherein the storage module of the detecting device further stores a set of user data, and whenever the mobile communication device attempts to connect with the detecting device, it is required that the detecting device receive verification data from the mobile communication device, the mobile communication device being unable to connect with the detecting device unless the detecting device determines that the verification data match the user data.

9. The sensing system of claim 5, wherein the storage module of the detecting device further stores a set of user data, and whenever the mobile communication device attempts to connect with the detecting device, it is required that the detecting device receive verification data from the mobile communication device, the mobile communication device being unable to connect with the detecting device unless the detecting device determines that the verification data match the user data.

10. The sensing system of claim 6, wherein the storage module of the detecting device further stores a set of user data, and whenever the mobile communication device attempts to connect with the detecting device, it is required that the detecting device receive verification data from the mobile communication device, the mobile communication device being unable to connect with the detecting device unless the detecting device determines that the verification data match the user data.

11. The sensing system of claim 7, wherein the storage module of the detecting device further stores a set of user data, and whenever the mobile communication device attempts to connect with the detecting device, it is required that the detecting device receive verification data from the mobile communication device, the mobile communication device being unable to connect with the detecting device unless the detecting device determines that the verification data match the user data.

12. The sensing system of claim 8, wherein the setting data for the electrical appliance further comprise a scheduled time and, when the detecting device receives the setting data for the electrical appliance and determines that a current time does not match the scheduled time in the setting data, the detecting device cuts off the electric signal transmitted from the power supply unit.

13. The sensing system of claim 9, wherein the setting data for the electrical appliance further comprise a scheduled time and, when the detecting device receives the setting data for the electrical appliance and determines that a current time does not match the scheduled time in the setting data, the detecting device cuts off the electric signal transmitted from the power supply unit.

14. The sensing system of claim 10, wherein the setting data for the electrical appliance further comprise a scheduled time and, when the detecting device receives the setting data for the electrical appliance and determines that a current time does not match the scheduled time in the setting data, the detecting device cuts off the electric signal transmitted from the power supply unit.

15. The sensing system of claim 11, wherein the setting data for the electrical appliance further comprise a scheduled time and, when the detecting device receives the setting data for the electrical appliance and determines that a current time does not match the scheduled time in the setting data, the detecting device cuts off the electric signal transmitted from the power supply unit.
